(19) United States
(12) Patent Application Publication
(10) Pub. No.: US 2026/0183804 A1
(43) Pub. Date: Jul. 2, 2026

(54) SUBSTRATE CLEANING DEVICE, SUBSTRATE PROCESSING APPARATUS, METHOD, AND STORAGE MEDIUM

(71) Applicant: EBARA CORPORATION, Tokyo (JP)

(72) Inventors: MEGUMI UNO, Tokyo (JP); CHIKAKO TAKATOH, Tokyo (JP)

(73) Assignee: EBARA CORPORATION, Tokyo (JP)

(21) Appl. No.: 19/414,203

(22) Filed: Dec. 9, 2025

(30) Foreign Application Priority Data
Dec. 26, 2024 (JP) 2024-230341

(51) Int. Cl. B08B 1/50; B08B 1/34; B08B 13/00; G01N 21/65; H10P 70/00

(52) U.S. Cl. CPC B08B 1/50; B08B 1/34; B08B 13/00; G01N 21/65; H10P 70/60

(57) ABSTRACT

A substrate cleaning device includes: a cleaning member, which is a cleaning member that cleans a polished substrate and moves between a cleaning position of cleaning the substrate and a retract position of cleaning the cleaning member; and a measurement part irradiating, at the retract position, the cleaning member with light and receiving scattered light or reflected light from the cleaning member, thereby measuring a residual amount of abrasive particles remaining on the cleaning member.

### CROSS-REFERENCE TO RELATED APPLICATION

This application claims the priority benefit of Japan application serial no. 2024-230341, filed on Dec. 26, 2024. The entirety of the above-mentioned patent application is hereby incorporated by reference herein and made a part of this specification.

### BACKGROUND

### Technical Field

The invention relates to a substrate cleaning device, a substrate processing apparatus, a method, and a storage medium.

### Description of Related Art

In a substrate cleaning device that cleans a substrate such as a polished wafer, cleaning members such as roll cleaning members and pencil cleaning members are used. Such cleaning members are cleaned by a self-cleaning part that cleans the cleaning members themselves.

Conventionally, a technology is known for measuring the degree of cleanliness of a cleaning member by measuring the adsorption force of the cleaning member in order to confirm whether cleaning of the cleaning member is being performed (see Patent Document 1).

However, no technology has been proposed for measuring the residual amount of the abrasive particles (slurry components used during wafer polishing) remaining on the cleaning member.

### PRIOR ART DOCUMENT(S)

### Patent Document(s)

[Patent Document 1] Japanese Patent Application Laid-Open Publication No. 2022-95360

The invention is configured to measure the residual amount of abrasive particles remaining on a cleaning member that cleans a polished substrate.

### SUMMARY

A substrate cleaning device according to an aspect of the invention includes: a cleaning member, which is a cleaning member that cleans a polished substrate and moves between a cleaning position of cleaning the substrate and a retract position of cleaning the cleaning member; and a measurement part, irradiating, at the retract position, the cleaning member with light and receiving scattered light or reflected light from the cleaning member, thereby measuring a residual amount of the abrasive particles remaining on the cleaning member.

A substrate processing apparatus according to an aspect of the invention includes the substrate cleaning device according to any one of [1] to [4].

A method according to an aspect of the invention is a method for measuring a residual amount of the abrasive particles remaining on a cleaning member that cleans a polished substrate. The method includes: moving the cleaning member from a cleaning position of cleaning the substrate to a retract position of cleaning the cleaning member; and measuring, at the retract position, the residual amount of the abrasive particles remaining on the cleaning member by irradiating the cleaning member with light and receiving scattered light or reflected light from the cleaning member.

[7] A storage medium according to an aspect of the invention stores a program that

causes a computer to execute a method for measuring a residual amount of the abrasive particles remaining on a cleaning member that cleans a polished substrate. The method includes: moving the cleaning member from a cleaning position of cleaning the substrate to a retract position of cleaning the cleaning member; and measuring, at the retract position, the residual amount of the abrasive particles remaining on the cleaning member by irradiating the cleaning member with light and receiving scattered light or reflected light from the cleaning member.

### BRIEF DESCRIPTION OF THE DRAWINGS

FIG. 1 is a diagram showing an example of a schematic configuration of a substrate processing apparatus.

FIG. 2 is a diagram showing an example of a schematic configuration of a substrate cleaning device using a roll cleaning member.

FIG. 3 is a diagram showing an example of a schematic configuration of a substrate cleaning device using a pencil cleaning member.

FIG. 4 is a diagram showing an example of a functional configuration of a substrate cleaning device.

FIG. 5 is a diagram showing an example of a hardware configuration of a substrate cleaning device.

FIG. 6 is a diagram describing a measurement method for abrasive particles remaining on a cleaning member.

FIG. 7 is a diagram describing measurement locations measured by a measurement part.

FIG. 8 is a diagram describing measurement of a nodule surface of a cleaning member.

FIG. 9 is a diagram describing an example of a measurement method for a cleaning member by a measurement part.

FIG. 10 is a diagram describing another example of a measurement method for a cleaning member by a measurement part.

FIG. 11 is a diagram showing an example of a spectrum measured by a measurement part.

FIG. 12 is a diagram showing an example of measurement results displayed in a map format on a display.

FIG. 13 is a diagram showing an example of operation of a substrate cleaning device according to the embodiment.

### DESCRIPTION OF THE EMBODIMENTS

[1] A substrate cleaning device according to an aspect of the invention includes: cleaning member, which is a cleaning member that cleans a polished substrate and moves between a cleaning position of cleaning the substrate and a retract position of cleaning the cleaning member; and a measurement part, irradiating, at the retract position, the cleaning member with light and receiving scattered light or reflected light from the cleaning member, thereby measuring a residual amount of the abrasive particles remaining on the cleaning member.

[2] In a substrate cleaning device according to an aspect of the invention, in [1]above, the measurement part measures the residual amount of the abrasive particles by irradiating the cleaning member with excitation light and receiving Raman scattered light from the cleaning member.

[3] A substrate cleaning device according to an aspect of the invention, in [1]or [2] above, further includes: a determination part, determining whether to replace the cleaning member based on a measurement result by the measurement part.

[4] In a substrate cleaning device according to an aspect of the invention, in any one of [1] to [3] above, the cleaning member has multiple nodules on a surface of the cleaning member, and the substrate cleaning device further includes a display control part that displays a measurement result by the measurement part on a display part in a map format corresponding to the nodules.

[5] A substrate processing apparatus according to an aspect of the invention includes the substrate cleaning device according to any one of [1] to [4].

[6] According to a method according to an aspect of the invention is a method for measuring a residual amount of the abrasive particles remaining on a cleaning member that cleans a polished substrate. The method includes: moving the cleaning member from a cleaning position of cleaning the substrate to a retract position of cleaning the cleaning member; and measuring, at the retract position, the residual amount of the abrasive particles remaining on the cleaning member by irradiating the cleaning member with light and receiving scattered light or reflected light from the cleaning member.

[7] A storage medium according to an aspect of the invention stores a program that causes a computer to execute a method for measuring a residual amount of the abrasive particles remaining on a cleaning member that cleans a polished substrate. The method includes: moving the cleaning member from a cleaning position of cleaning the substrate to a retract position of cleaning the cleaning member; and measuring, at the retract position, the residual amount of the abrasive particles remaining on the cleaning member by irradiating the cleaning member with light and receiving scattered light or reflected light from the cleaning member.

According to the invention, it is possible to measure a residual amount of the abrasive particles remaining on a cleaning member that cleans a polished substrate.

Hereinafter, each embodiment will be described with reference to the drawings. However, unnecessarily detailed descriptions may be omitted. For example, detailed descriptions of already well-known matters or redundant descriptions of substantially identical configurations may be omitted. This is to avoid making the following description unnecessarily redundant and to facilitate understanding by those skilled in the art.

### Configuration of Substrate Processing Apparatus

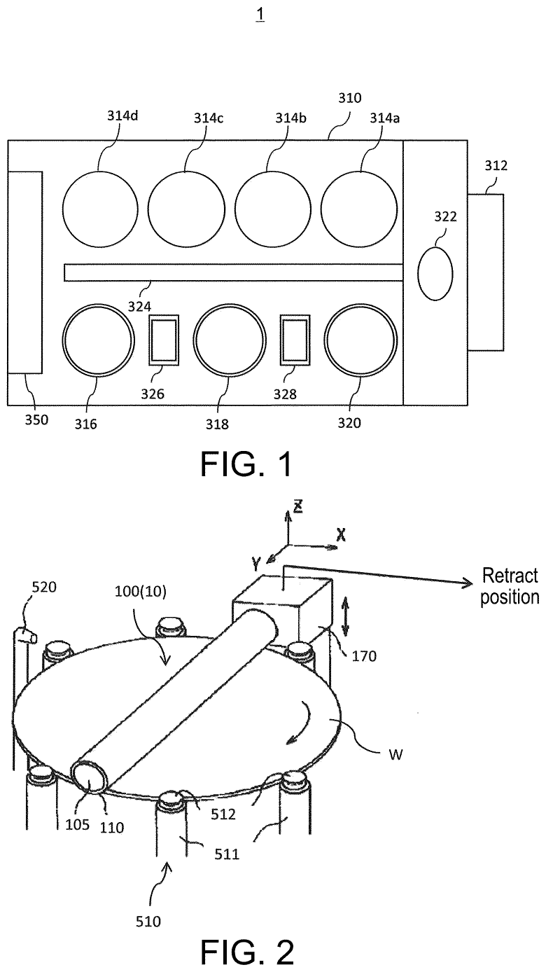

As shown in FIG. 1, the substrate processing apparatus 1 of the embodiment includes a substantially rectangular housing 310 and a load port 312 on which a substrate cassette for stocking multiple substrates W is placed. The load port 312 is disposed adjacent to the housing 310. An open cassette, a standard mechanical interface (SMIF) pod, or a front opening unified pod (FOUP) can be mounted on the load port 312. The SMIF pod and FOUP are sealed containers that can maintain an environment independent from the external space by housing a substrate cassette inside and covering the substrate cassette with partition walls. Examples of the substrate W include a semiconductor wafer and the like.

Inside the housing 310, multiple (four in the configuration shown in FIG. 1) polishing units 314a to 314d, a first cleaning unit 316 and a second cleaning unit 318 for cleaning the substrate W after polishing, and a drying unit 320 for drying the substrate W after cleaning are accommodated. The polishing units 314a to 314d are arranged along the longitudinal direction of the substrate processing apparatus 1, and the cleaning units 316, 318 and the drying unit 320 are also arranged along the longitudinal direction of the substrate processing apparatus 1. According to the substrate processing apparatus 1 of the embodiment, various substrates W can be polished in the manufacturing processes of semiconductor wafers with a diameter of 300 mm or 450 mm, flat panels, image sensors such as a complementary metal oxide semiconductors (CMOS) and charge coupled devices (CCD), and magnetic films in magnetoresistive random access memories (MRAM). The configuration may include only the cleaning units 316, 318 and the drying unit 320 without providing a polishing unit for polishing the substrate W inside the housing 310 of the substrate processing apparatus 1.

A first transport robot 322 is disposed in a region surrounded by the load port 312, the polishing unit 314a located on the side of the load port 312, and the drying unit 320. Additionally, a transport unit 324 is disposed in parallel with the polishing units 314a to 314d and the cleaning units 316, 318 and the drying unit 320. The first transport robot 322 receives the substrate W before polishing from the load port 312 and transfers the substrate W to the transport unit 324, or takes out the substrate W after drying from the drying unit 320 and returns the substrate W to the load port 312.

A second transport robot 326 is disposed between the first cleaning unit 316 and the second cleaning unit 318 to transfer the substrate W between the first cleaning unit 316 and the second cleaning unit 318, and a third transport robot 328 is disposed between the second cleaning unit 318 and the drying unit 320 to transfer the substrate W between the second cleaning unit 318 and the drying unit 320. Furthermore, an overall control part 350 that controls the operation of each device of the substrate processing apparatus is disposed inside the housing 310. In the embodiment, a configuration in which the overall control part 350 is disposed inside the housing 310 is used for description, but the invention is not limited thereto, and the overall control part 350 may be disposed outside the housing 310, or the overall control part 350 may be provided at a remote location.

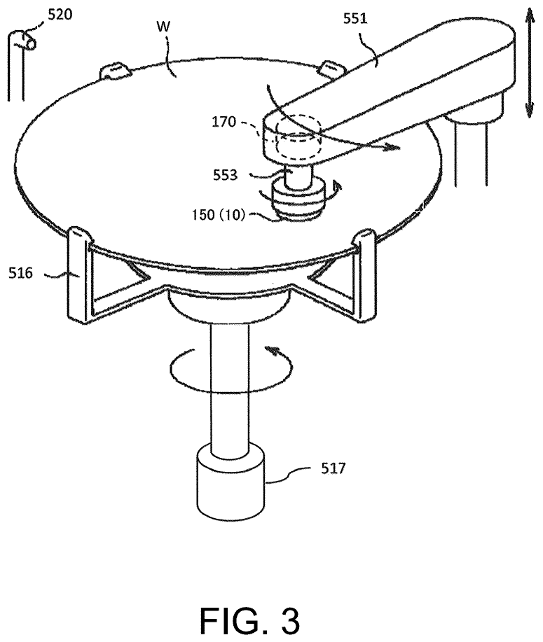

As the first cleaning unit 316, a roll cleaning device may be used that brings a roll cleaning member 100 (see FIG. 2) extending linearly over substantially the entire length of the diameter of the substrate W into contact in the presence of a cleaning liquid, and performs scrub cleaning of the surface of the substrate W while rotating around a central axis parallel to the substrate W. Additionally, as the second cleaning unit 318, a pencil cleaning device may be used that brings the contact surface of a cylindrical pencil cleaning member 150 (see FIG. 3) extending in the vertical direction into contact in the presence of the cleaning liquid, and moves the pencil cleaning member 150 in one direction while rotating to perform scrub cleaning of the surface of the substrate W. Furthermore, as the drying unit 320, a spin drying unit may be used that dries the substrate W by ejecting IPA vapor from a moving injection nozzle toward the substrate W that rotates while being held horizontally, and further dries the substrate W by a centrifugal force by rotating the substrate W at a high speed.

As the first cleaning unit 316, instead of a roll cleaning device, a pencil cleaning device similar to the second cleaning unit 318 may be used, or a two-fluid jet cleaning device that cleans the surface of the substrate W with a two-fluid jet may be used. Additionally, as the second cleaning unit 318, instead of a pencil cleaning device, a roll cleaning device similar to the first cleaning unit 316 may be used, or a two-fluid jet cleaning device that cleans the surface of the substrate W with a two-fluid jet may be used.

The cleaning liquid of the embodiment includes rinse liquid such as pure water (DIW), and chemical liquids such as ammonia hydrogen peroxide water (SC1), hydrochloric acid hydrogen peroxide water (SC2), sulfuric acid hydrogen peroxide water (SPM), and hydrofluoric acid. Unless otherwise specified in the embodiment, the cleaning liquid means a rinse liquid, a chemical liquid, or both of a rinse liquid and a chemical liquid.

As shown in FIG. 2 and FIG. 3, the substrate cleaning device includes a rotation holding mechanism that holds and rotates the substrate W, a drive part 170 that rotates the cleaning member 10, and a substrate cleaning liquid supply part 520 that supplies the cleaning liquid to the substrate W.

In the configuration shown in FIG. 2, the rotation holding part 510 performs the functions of both the rotation part and the holding part, and in this case as well, the substrate cleaning device includes both the rotation part and the holding part. On the other hand, in the aspect shown in FIG. 3, the substrate W is held by the holding part 516, and the substrate W is rotated by the holding part 516 being rotated by the rotation part 517.

In the configuration shown in FIG. 2, the rotation holding part 510 as the rotation holding mechanism includes a spindle 511 and a piece 512 provided at the tip of the spindle 511. In the configuration shown in FIG. 3, a rotating shaft 553 for rotating the pencil cleaning member 150 is provided on the tip side of the swing arm 551, and a drive part 170 for rotating the rotating shaft is provided.

The cleaning member 10 is, as an example, the roll cleaning member 100 as shown in FIG. 2 described above or the pencil cleaning member 150 as shown in FIG. 3. Hereinafter, the cleaning member 10 is used as a concept that includes the roll cleaning member 100 and the pencil cleaning member 150. The cleaning member 10 is typically used in post-CMP cleaning.

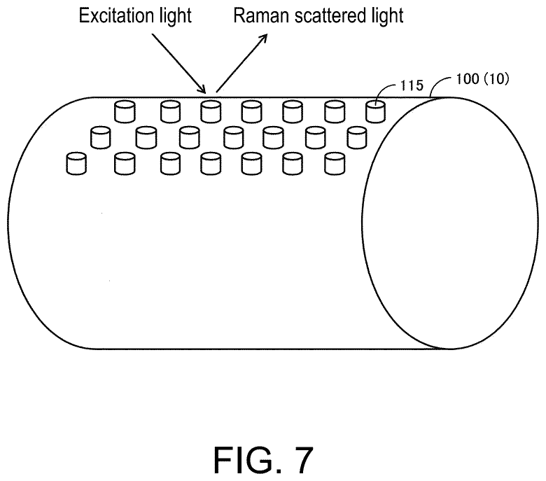

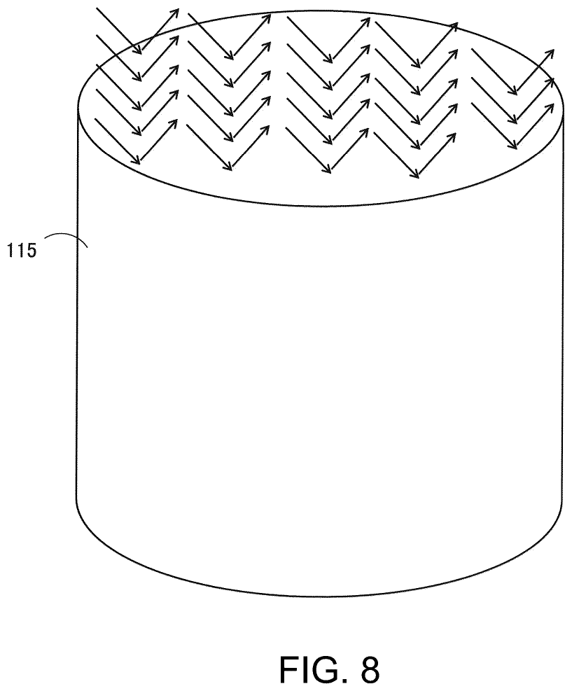

The roll cleaning member 100 shown in FIG. 2 is rotatable around a rotating shaft. The roll cleaning member 100 may have a roll body part 110 that is detachably or fixedly attached to a roll mounting part 105, and multiple nodules 115 (see FIG. 7) may be provided on the surface of the roll body part 110.

The roll cleaning member 100 may be made of a polyvinyl alcohol (PVA) sponge material or polyvinyl acetal obtained by reacting PVA, such as polyvinyl formal (PVFM), polyvinyl acetate (PVAc), etc. The PVA sponge material can be prepared from homopolymers of polyvinyl acetate, etc. As materials for the roll cleaning member 100, other moldable materials such as nylon, polyurethane, or a combination of polyurethane and PVA, or other copolymers that do not scratch the substrate surface and provide suitable material removal for the process can be used.

The pencil cleaning member 150 may be made of a PVA sponge material or polyvinyl formal (PVFM) obtained by reacting PVA. As a material for the pencil cleaning member 150, nylon, polyurethane, or a combination of polyurethane and PVA may be used.

As contaminants (such as abrasive particles included in slurry) that are adhered to the substrate W such as a semiconductor substrate or a glass substrate transfer to the side of the cleaning member 10 with the cleaning of the substrate W, repeating the cleaning of the substrate W in that state causes scratches to occur and clearly deteriorates the cleaning performance. For this reason, the cleaning member 10 may be cleaned and purified periodically (for example, every time cleaning of one lot of substrates W is finished). Specifically, the cleaning member 10 may be moved from a cleaning position of cleaning the substrate W to a retract position of cleaning the cleaning member 10 itself (self-cleaning), and cleaning of the cleaning member 10 (self-cleaning) may be performed by bringing it into rotational contact with a cleaner of a self-cleaning part (see FIG. 6) provided in a cleaning tank.

### Functional Configuration

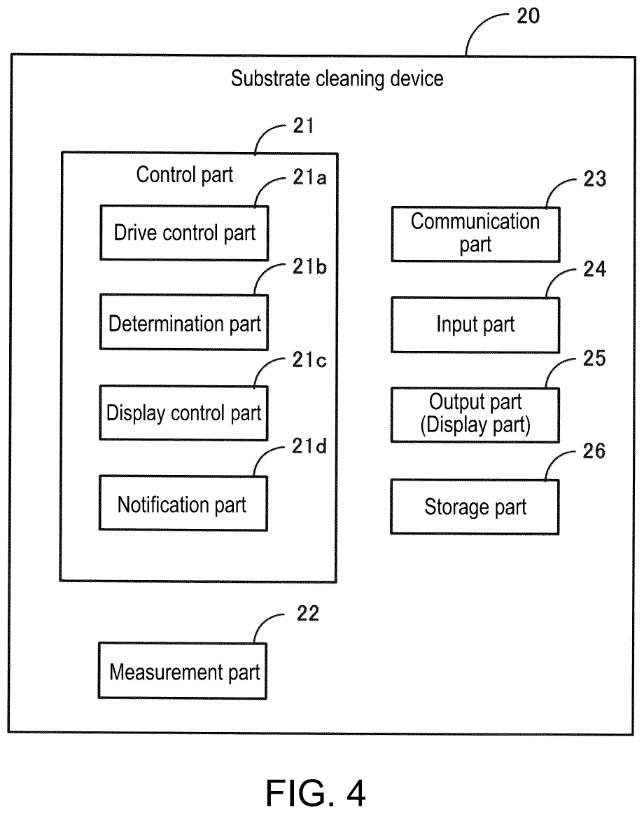

FIG. 4 is a diagram showing an example of the functional configuration of the substrate cleaning device 20 (the first cleaning unit 316 and/or the second cleaning unit 318 in FIG. 1) according to the embodiment. As shown in FIG. 4, the substrate cleaning device 20 includes a control part 21, a measurement part 22, a communication part 23, an input part 24, an output part (display part) 25, and a storage part 26. In the figure, the functional units that perform the respective functions can be said to be means for performing the respective functions.

The control part 21 includes a drive control part 21a, a determination part 21b, a display control part 21c, and a notification part 21d.

The drive control part 21a controls a motor for moving the cleaning member 10 between a cleaning position of cleaning the substrate W and a retract position of cleaning the cleaning member 10 itself (self-cleaning), and a motor for rotating the cleaning member 10 at the time of cleaning of the substrate W or at the time of self-cleaning.

The determination part 21b determines whether to replace the cleaning member 10 based on measurement results by the measurement part 22. Specifically, the determination part 21b determines that self-cleaning of the cleaning member 10 ends in the case where the residual amount of the abrasive particles measured by the measurement part 22 is below a threshold, and determines that self-cleaning is required again in the case where the residual amount of the abrasive particles is equal to or above the threshold. Also, the determination part 21b determines that it is necessary to replace the cleaning member 10 in the case where the residual amount of the abrasive particles is equal to or above the threshold even after self-cleaning is performed a predetermined number of times.

The display control part 21c displays measurement results by the measurement part 22 on the display part 25. The display control part 21c may display the measurement results by the measurement part 22 on the display part 25 in a map format corresponding to the nodules 115.

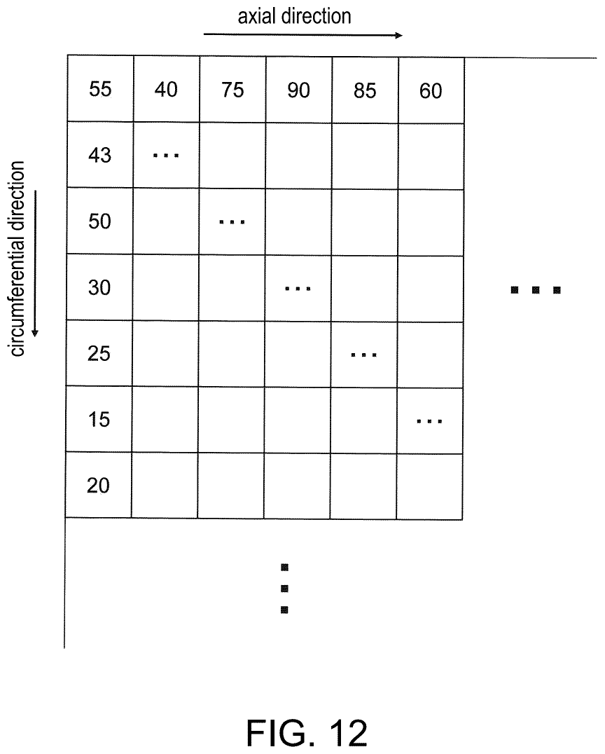

FIG. 12 is a diagram showing an example of measurement results displayed in a map format on the display part 25. In FIG. 12, each cell corresponds to each nodule 115 distributed in the axial direction and the circumferential direction of the cleaning member 10. The numerical value of each cell indicates the residual amount of the abrasive particles measured by the measurement part 22. The residual amount may be, for example, a value normalized with a certain reference value as 100. By displaying the residual amount in a map format in this way, it becomes possible to visually grasp portions that are not sufficiently cleaned (portions where many abrasive particles remain) in the cleaning member 10. Based on the results, self-cleaning of the cleaning member 10 can be efficiently performed by intensively re-cleaning a portion where many abrasive particles remain.

The notification part 21d performs notification according to a determination result by the determination part 21b. Specifically, the notification part 21d outputs a display or a sound that urges replacement of the cleaning member via the output part 25 of the substrate cleaning device 20 in the case where the determination part 21b determines that it is necessary to replace the cleaning member 10. Also, the notification part 21d may perform the notification to a terminal device via a network by the communication part 23.

The measurement part 22 measures the residual amount of the abrasive particles remaining on the cleaning member 10 by irradiating the cleaning member 10 with light and receiving scattered light or reflected light from the cleaning member 10 in a state where the cleaning member 10 moves to the retract position.

FIG. 6 is a diagram describing the measurement of the residual amount of the abrasive particles by the measurement part 22. As shown in FIG. 6, the cleaning member 10 rotates at the self-cleaning part in the cleaning tank in order to perform cleaning on the cleaning member 10 itself (self-cleaning) at the retract position, and the cleaning member 10 makes rotational contact with the cleaner. In this way, abrasive particles adhering to the surface of the cleaning member 10 and the nodules 115 (illustration omitted in FIG. 6) are washed out.

The measurement part 22 is, for example, a Raman spectrometer, and irradiates laser (for example, with a wavelength around 532 nm) as excitation light from the light source unit to the cleaning member 10. Fibers, mirrors, etc., are used in the optical path inside the measurement part 22. The Raman scattered light from the cleaning member 10 is divided in a light reception part to obtain a Raman spectrum. By using the Raman spectrometer, the abrasive particle residual state on the surface of the cleaning member can be monitored in a non-destructive and wet state.

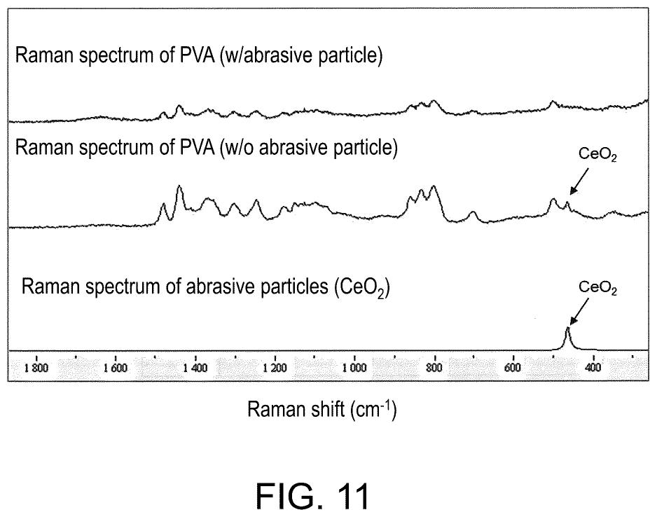

FIG. 11 is a diagram showing an example of a Raman spectrum measured by the measurement part 22. From the top of FIG. 11, the Raman spectrum of PVA without abrasive particles (cleaning member 10), the Raman spectrum of PVA with abrasive particles (cleaning member 10), and the Raman spectrum of abrasive particles (CeO₂) are shown. In the Raman spectrum of PVA with abrasive particles (cleaning member 10), there is a peak of Raman shift of abrasive particles (CeO₂) around wavenumber 475 cm⁻¹. Therefore, by detecting the peak of Raman shift of abrasive particles from the Raman spectrum of the cleaning member 10, the presence or absence of abrasive particles can be detected, and the residual amount of the abrasive particles can be measured (measurement of residual amount will be described later). As an example, the case where the abrasive particles are ceria (CeO₂) has been described, but the residual amount can be measured similarly even with other abrasive particles such as silica (SiO₂). That is, by detecting the peak of Raman shift of the abrasive particles to be measured, the presence or absence and the residual amount of the abrasive particles can be measured.

The measurement of the cleaning member 10 by the measurement part 22 may be performed multiple times while changing the positions on the surface of the nodules 115.

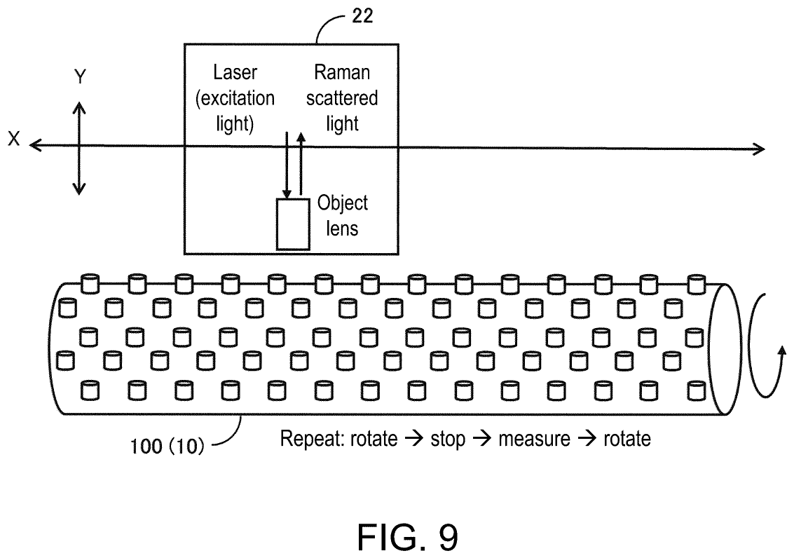

Also, as shown in FIG. 9, the measurement part 22 may be moved in the X-direction (axial direction of the cleaning member 10) and Y-direction (optical axis direction of the objective lens of the measurement part 22), and measurement may be performed for each nodule 115 while rotating the cleaning member 10. Specifically, if a measurement instruction is given from the control part 21 to the measurement part 22, the control part 21 moves the measurement part 22 in Y-axis direction (object side of the objective lens) so that the measurement part 22 approaches the cleaning member 10. Then, while moving the measurement part 22 in X-axis direction, measurement is sequentially performed in the unit of the nodules 115 from one end of the cleaning member 10 (for example, the left end in FIG. 9). Once the measurement ends up to the other end (for example, the right end in FIG. 9), the control part 21 rotates the cleaning member 10 by a predetermined angle (for example, by one row of the nodules 115) and moves the measurement part 22 in X-axis direction to return to the one end side, and starts the measurement again. The operation is repeated, and once a complete set of measurements finish, the control part 21 moves the measurement part 22 in Y-axis direction so that the measurement part 22 is separated from the cleaning member 10.

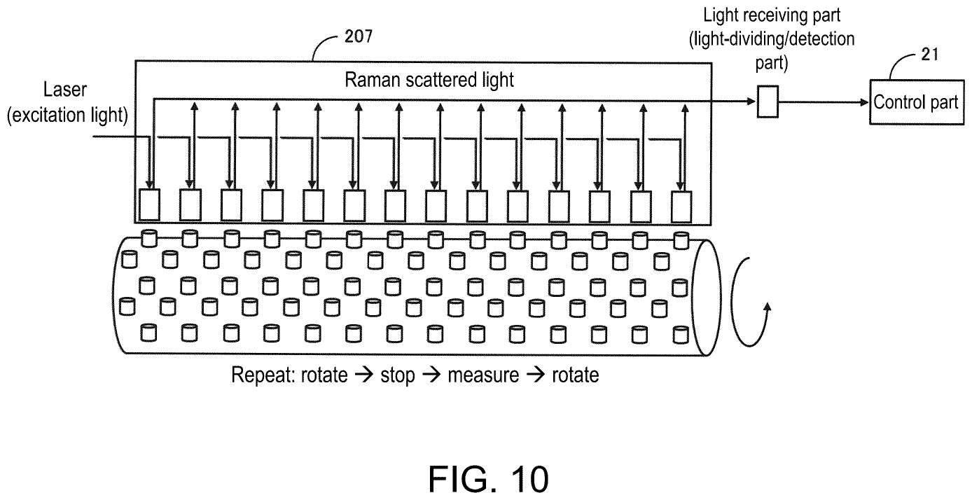

As shown in FIG. 10, multiple objective lenses corresponding to the nodules 115 of the cleaning member 10 (for example, a predetermined number in the axial direction of the cleaning member 10) may be provided in the measurement part 22. In this case, since it is unnecessary to exert control to move the measurement part 22 in the axial direction of the cleaning member 10 (X-direction in FIG. 9), the measurement time of the cleaning member 10 can be shortened.

Here, the measurement of the residual amount of the abrasive particles will be described. As an index of the residual amount, the intensity average of the peaks of the Raman shift of the abrasive particles measured by the measurement part 22 may be used. In this case, the average of the measurement results (peak intensity) of the nodules 115 may be used, or the average of the measurement results (peak intensity) of the nodules 115 located at specific measurement points (for example, three points at the left end, center, and right end in the axial direction of the cleaning member 10) may be used (in the case where multiple measurements are performed on one nodule 115, the average thereof is used). Also, a peak count number may be used instead of the peak intensity.

As an example, the measurement part 22 has been described as a Raman spectrometer, but an infrared spectrometer such as FTIR may be used as the measurement part 22. Also, as the measurement part 22, an optical measurement device that irradiates the light in a wavelength corresponding to the absorption peak of abrasive particles and detects the reception amount of the reflected light and/or scattered light may be used.

Referring to FIG. 4 again, the communication part 23 is a communication interface between the substrate cleaning device 20 and other devices. The communication part 23 also transmits and receives the information with a server and a terminal device via a network.

The input part 24 is a component for users of the substrate cleaning device 20 (including users and maintenance personnel of the substrate cleaning device 20) to input information, and is, for example, a keyboard, a mouse, a touch panel, a microphone, a gesture input device, or the like. The input part 24 may be provided in other parts of the substrate processing apparatus 1 including the substrate cleaning device 20.

The output part (display part) 25 is an interface for outputting various information (images and audio) from the substrate cleaning device 20 to the user, and is, for example, a video display device (display part) such as a liquid crystal display or a speaker. When the output part 25 is formed as a display part, a GUI for receiving the operation from the user is displayed on the display part. The output part 25 may be provided in other portions of the substrate processing apparatus 1 including the substrate cleaning device 20.

The storage part 26 is, for example, a data storage such as an internal memory or an external memory (a SD memory card, etc.). The storage part 26 stores various data handled by the control part 21 and various information downloaded by the communication part 23 from servers via a network. The storage part 26 does not necessarily have to be provided within the substrate cleaning device 20, and a portion or the entirety of the storage part 26 may be provided within another device communicably connected to the substrate cleaning device 20 via a network.

### Hardware Configuration

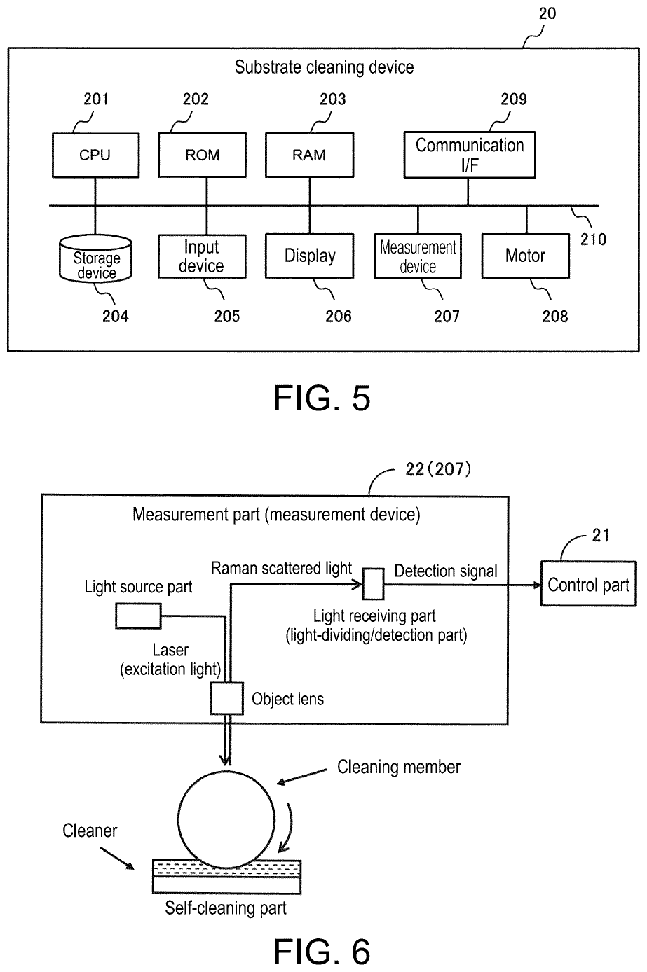

Next, the hardware configuration of the substrate cleaning device 20 according to the embodiment will be described. FIG. 5 is a block diagram showing an example of the hardware configuration of the substrate cleaning device 20 according to the embodiment.

In the substrate cleaning device 20, a CPU 201 is a processing apparatus that controls the operation of the entire substrate cleaning device 20. A ROM 202 is a non-volatile memory that stores a control program executed by the CPU 201 and various data. A RAM 203 is a volatile memory used for load areas and work areas of the program executed by the CPU 201. A storage device 204 is a storage means for storing various information, and may be built in the main body of the substrate cleaning device 20 or may be a component where a storage medium is removable. An input device 205 is a device for the user of the substrate cleaning device 20 to input information, and is, for example, a keyboard, a mouse, a touch panel, a microphone, or the like. A display 206 is a display device that displays various information (user interfaces, etc.) A measurement device 207 is a device that measures the residual amount of the abrasive particles remaining on the cleaning member 10. Specifically, the measurement device 207 includes a light source unit and a light receiving unit, and measures the residual amount of the abrasive particles by irradiating light of a specific wavelength band from the light source unit to the cleaning member and having the light receiving unit receive the reflected light or scattered light from the cleaning member. A motor 208 includes a motor for moving the cleaning member 10 between the cleaning position of cleaning the substrate W and the retract position of cleaning the cleaning member 10 itself (self-cleaning), and a motor for rotating the cleaning member 10 during cleaning of the substrate W or during self-cleaning. A communication I/F (interface) 209 is an interface for connecting to other devices or networks not shown. A bus 210 is a bus line that connects the components to each other.

At least one of the configurations may be provided in the substrate processing apparatus 1.

### Example of Operation

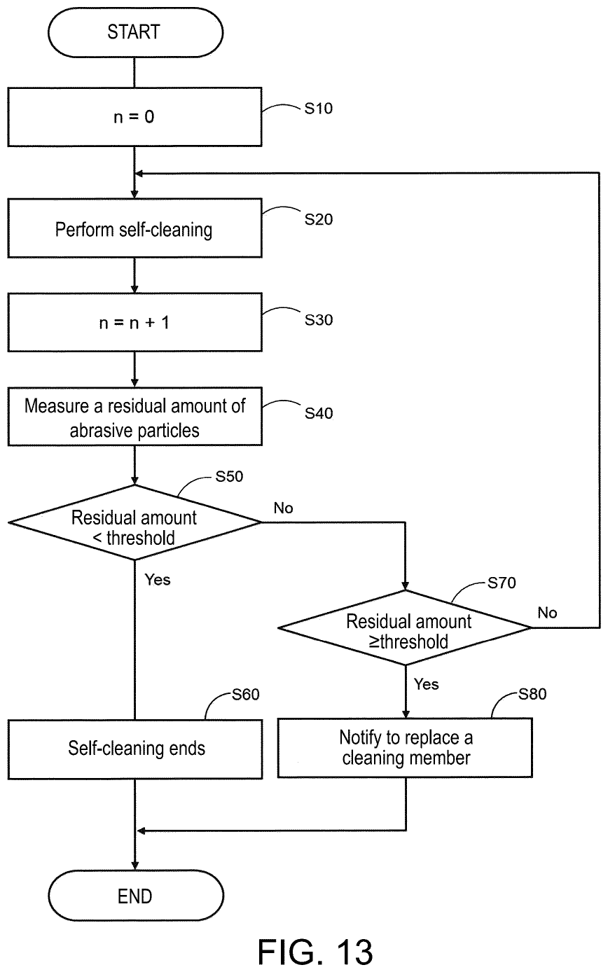

Next, an example of the operation of the substrate cleaning device 20 (substrate processing apparatus 1) according to the embodiment will be described. FIG. 13 is a flowchart showing an example of the operation during self-cleaning of the cleaning member 10 of the substrate cleaning device 20.

First, the control part 21 moves the cleaning member 10 from the cleaning position of cleaning the substrate W to the retract position of cleaning of the cleaning member 10 itself (self-cleaning), and resets a self-cleaning count n to 0 (Step S10).

Next, the control part 21 executes self-cleaning of the cleaning member 10 (Step S20).

When the self-cleaning of the cleaning member 10 ends, the control part 21 increments the self-cleaning count n of the cleaning member 10 to n+1 (Step S30).

Then, the control part 21 performs measurement of the residual amount of the abrasive particles remaining on the cleaning member 10 by the measurement part 22 (Step S40).

The control part 21 determines whether the residual amount of the abrasive particles measured by the measurement part 22 is below the threshold (Step S50).

Then, in the case where the determination is affirmative, the control part 21 determines that the self-cleaning of the cleaning member 10 ends (Step S60).

Meanwhile, in the case where the residual amount of the abrasive particles measured by the measurement part 22 is equal to or above the threshold (in the case where the determination in Step S50 is negative), the control part 21 further determines whether the self-cleaning count n of the cleaning member 10 is above the threshold (predetermined number of times) (Step S70).

In the case where the determination is affirmative, the control part 21 determines that is necessary to replace the cleaning member 10, and the notification part 21d performs notification to urge the user of the substrate cleaning device 20 to replace the cleaning member 10 (Step S80).

Meanwhile, in the case where the self-cleaning count n of the cleaning member 10 is below the threshold (predetermined number of times) (in the case of the determination in Step S70 being negative), the process returns to Step S20, and the control part 21 executes the self-cleaning of the cleaning member 10 again.

According to the above configuration, the residual amount of the abrasive particles remaining on the cleaning member can be measured. Accordingly, it is possible to grasp the accumulation state of the abrasive particles on the cleaning member surface during the cleaning process, and allows the timings of self-cleaning and brush replacement to be determined suitably.

In the embodiment, an example in the case where the cleaning member 10 measured by the measurement part 22 is a roll cleaning member is described, but the cleaning member 10 measured by the measurement part 22 may be a pencil cleaning member as shown in FIG. 3. In this case, the measurement part 22 may be provided below the pencil-type cleaning member 10 at the retract position, and measurement light (excitation light) may be irradiated from below the cleaning member 10 after the self-cleaning of the cleaning member 10 ends.

Any portion or the entirety of the respective functional units described in the specification may be realized by a program. The program mentioned in the specification may be non-temporarily recorded on a computer-readable storage medium and distributed, may be distributed via communication lines such as the Internet (including wireless communication), or may be distributed in a state installed on any terminal device.

Based on the above description, those skilled in the art may be able to conceive additional effects and various modification examples of the embodiment, but the configurations of the embodiment are not limited to the individual embodiments described above. Various additions, changes, and partial deletions are possible within the scope that does not depart from the conceptual idea and spirit of the embodiment derived from the content defined in the claims and equivalents thereof.

For example, what is described as one device (or member, the same applies hereinafter) in the specification (including what is drawn as one device in the drawings) may be realized by multiple devices. Conversely, what is described as multiple devices in the specification (including what is drawn as multiple devices in the drawings) may be realized by one device. Alternatively, part or all of the means or functions included in a certain device (for example, a server) may be included in another device (for example, a terminal device).

Also, not all matters described in the specification are essential requirements. In particular, matters described in the specification but not described in the claims can be said to be additional matters that are optional.

The present applicant merely knows the documented known inventions described in the literature listed in the “Prior Art Documents” section of the specification, and it should also be noted that the invention does not necessarily aim to solve the problems in the same documented known inventions. The problems that the invention seeks to solve should be recognized by considering the entire specification. For example, in the specification, in the case of a description that a predetermined effect is achieved by a specific configuration, it can also be said that the problem that is the reverse of the predetermined effect is solved. However, this does not necessarily mean that such a specific configuration is an essential requirement.

What is claimed is:

1. A substrate cleaning device, comprising:
a cleaning member, which is a cleaning member that cleans a polished substrate and moves between a cleaning position of cleaning the substrate and a retract position of cleaning the cleaning member; and
a measurement part, irradiating, at the retract position, the cleaning member with light and receiving scattered light or reflected light from the cleaning member, thereby measuring a residual amount of abrasive particles remaining on the cleaning member.

2. The substrate cleaning device as claimed in claim 1, wherein the measurement part measures the residual amount of the abrasive particles by irradiating the cleaning member with excitation light and receiving Raman scattered light from the cleaning member.

3. The substrate cleaning device as claimed in claim 1, further comprising: a determination part, determining whether to replace the cleaning member based on a measurement result by the measurement part.

4. The substrate cleaning device as claimed in claim 1, wherein the cleaning member has a plurality of nodules on a surface of the cleaning member, and
the substrate cleaning device further comprises a display control part that displays a measurement result by the measurement part on a display part in a map format corresponding to the nodules.

5. A substrate processing apparatus, comprising the substrate cleaning device as claimed in claim 1.

6. A method for measuring a residual amount of abrasive particles remaining on a cleaning member that cleans a polished substrate, the method comprising:
moving the cleaning member from a cleaning position of cleaning the substrate to a retract position of cleaning the cleaning member; and
measuring, at the retract position, the residual amount of the abrasive particles remaining on the cleaning member by irradiating the cleaning member with light and receiving scattered light or reflected light from the cleaning member.

7. A computer-readable storage medium, storing a program which, causes a computer to execute a method for measuring a residual amount of abrasive particles remaining on a cleaning member that cleans a polished substrate, the method comprising:
moving the cleaning member from a cleaning position of cleaning the substrate to a retract position of cleaning the cleaning member; and
measuring, at the retract position, the residual amount of the abrasive particles remaining on the cleaning member by irradiating the cleaning member with light and receiving scattered light or reflected light from the cleaning member.
